(19) United States
(12) Patent Application Publication
(10) Pub. No.: US 2005/0263865 A1
(43) Pub. Date: Dec. 1, 2005

(54) IC chip package

(76) Inventor: Cheng-Chiao Wu, Taichung (TW)

Correspondence Address: BIRCH STEWART KOLASCH & BIRCH, PO BOX 747, FALLS CHURCH, VA, 22040-0747, US

(21) Appl. No.: 10/917,445

(22) Filed: Aug. 13, 2004

(30) Foreign Application Priority Data
May 28, 2004 (TW) 093115443

(51) Int. Cl. H01L 23/495

(52) U.S. Cl. 257/678

(57) ABSTRACT

An IC chip package includes a carrier having a top side, a bottom side, a receiving chamber, and a plurality of solder areas and non-solder areas alternately arranged around the opening of the receiving chamber, an IC chip fixedly mounted inside the receiving chamber, a plurality of solder wires respectively electrically connected between solder pads of the solder areas of the carrier and the IC chip, a cover for sealing the opening of the receiving chamber, a support means held between the non-solder areas of the carrier and the cover, and a bonding agent sealing gaps between the cover and the carrier for fixing the cover to the carrier.

### BACKGROUND OF THE INVENTION

1. Field of the Invention

The present invention relates to integrated circuit (IC) chip package, and more particularly to a small-scale IC chip package.

2. Description of the Related Art

FIG. 1 shows a conventional small-sale IC chip package. The IC chip package is comprised of a carrier 1, a receiving chamber 2 formed in the carrier 1 and having an opening 3 at a top side thereof, a plurality of solder pads 4 disposed at the top side of the carrier 1 around the opening 3, an IC chip 5 fixedly mounted inside the receiving chamber 2, a plurality of solder wires 6 respectively electrically connected between the solder pads 4 and the IC chip 5, a bonding agent 7 disposed at the top side of the carrier 1 around the opening 3, and a cover 8 bonded to the bonding agent 7 to seal the opening 3 of the carrier 1. Because the solder pads 4 are provided at the top side of the carrier 1 around the opening 3, it is not necessary to provide an operating space in the receiving chamber 2 for wire bonding, thereby diminishing the size of the IC chip package.

However, when the opening 3 of the carrier 1 is sealed by the cover 8, the solder wires 6 and the solder pads 4 are directly squeezed by the cover 8; meanwhile, the solder wires 6 may be damaged or depart away from the solder pads 4 to incur malfunction of the IC chip 5, thereby deteriorating the package yield and increasing the production cost.

### SUMMARY OF THE INVENTION

The present invention has been accomplished under the circumstances in view. It is the main object of the present invention to provide an improved IC chip package, which size is greatly reduced. It is another object of the present invention to provide an IC chip package, which solder wires are well protected from damage.

To achieve the foregoing objects of the present invention, an IC chip package is comprised of a carrier, an IC chip, a plurality of solder wires, a cover, a support member, and a bonding agent. The carrier includes a top side, a bottom side, a receiving chamber formed therein and having an opening, and a plurality of solder areas and non-solder areas alternately arranged around the opening of the receiving chamber. The IC chip is fixedly mounted inside the receiving chamber, having a plurality of solder pads. The solder wires are electrically connected respectively between the solder pads and the solder areas. The cover is mounted on the carrier to seal the opening of the receiving chamber. The support member is held between the non-solder areas of the carrier and the cover. The bonding agent is disposed at the junction between the carrier and the cover for fixing the cover to the carrier.

### BRIEF DESCRIPTION OF THE DRAWINGS

FIG. 1 is a sectional view of a conventional IC chip package.

FIG. 2 is a sectional view of a first preferred embodiment of the present invention.

FIG. 3 is a partial perspective view of the first preferred embodiment of the present invention.

FIG. 4 is a top view of the IC chip package, which cover is removed, according to the first preferred embodiment of the present invention.

FIG. 5 is a sectional exploded view of a second preferred embodiment of the present invention.

FIG. 6 is a top view of the IC chip package, which cover is removed, according to the second preferred embodiment of the present invention.

FIG. 7 is a sectional exploded view of a third preferred embodiment of the present invention.

FIG. 8 is a top view of the IC chip package, which cover is removed, according to the third preferred embodiment of the present invention.

FIG. 9 is a perspective view of a support member according to a fourth preferred embodiment of the present invention.

### DETAILED DESCRIPTION OF THE INVENTION

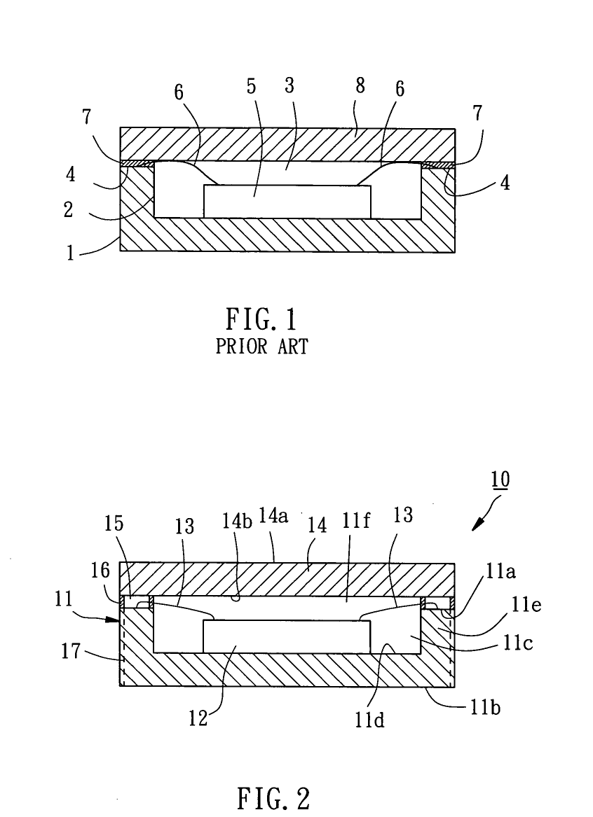

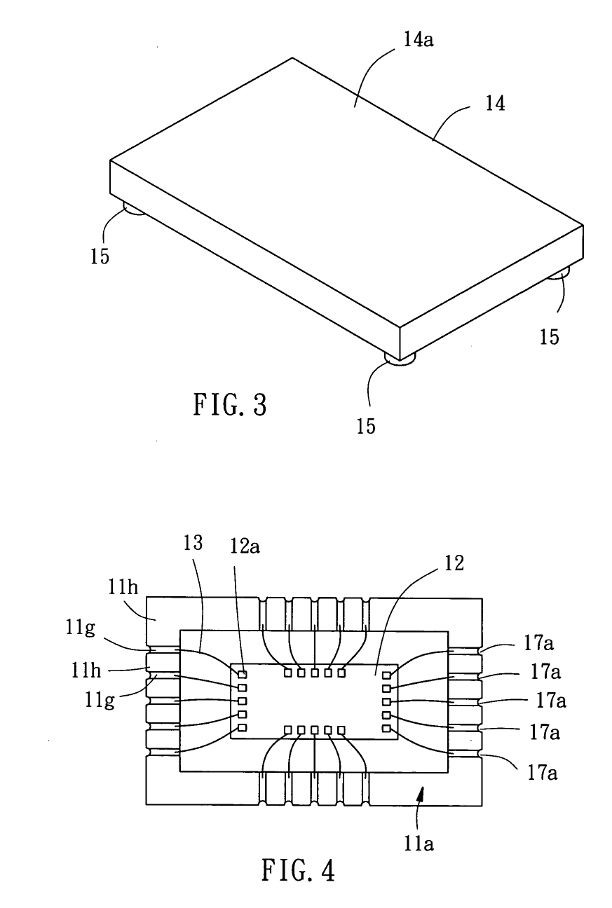

Referring to FIGS. 2-4, an IC chip package 10 in accordance with a first preferred embodiment of the present invention is shown comprised of a carrier 11, an IC chip 12, a plurality of solder wires 13, a cover 14, a support member 15, a bonding agent 16, and connecting means 17.

The carrier 11 is made of an electrically insulative material, such as plastics, fiberglass, reinforced plastics, ceramics, etc., having a top side 11a, a bottom side lib, a receiving chamber 11c, a bottom wall 11d located below the receiving chamber 11c, an upright peripheral wall 11e located around an edge of the bottom wall 11d, an opening 11f formed at a top side of the receiving chamber 11e, and a plurality of solder areas 11g and non-solder areas 11h, which are alternately arranged around the opening 11f. Each of the solder areas 11g can be a solder pad.

The IC chip 12 is fixedly bonded to the bottom wall 11d of the receiving chamber 11c, having a plurality of solder pads 12a at a top side thereof.

The solder wires 13 are made of metal material of high electric conductivity, such as aluminum or gold, each having an end bonded to the solder pad 12a of the IC chip 12 and the other end horizontally bonded to the solder area 11g of the carrier 11 by means of a wire bonder (not shown).

The cover 14 is mounted on the carrier 11 for sealing the opening 11f of the receiving chamber 11c and protecting the IC chip 12 against damage and contamination, having a top side 14a and a bottom side 14b.

The support member 15 is formed of a plurality of short legs protruded from the edge of the bottom side 14b of the cover 14. When the cover 14 seals the opening 11f of the receiving chamber 11c, the support member 15 is closely mounted on the non-solder areas 11h around the opening 11f.

The bonding agent 16 is disposed at the junction between the cover 14 and the carrier 11 for protecting the solder wires 13 and the solder areas 11g of the carrier 11 and fixing the cover 14 to the carrier 11 and sealing gaps formed between the cover 14 and the carrier 11 due to the support member 15, thereby sealing the receiving chamber 11c.

The connecting means 17 are provided for connecting the solder areas 11g to the outside of the carrier 11. According to this preferred embodiment, the connecting means 17 is comprised of a plurality of through holes 17a in communication between the solder areas 11g and the bottom side 11b of the carrier 11. When the IC chip package 10 is mounted in a circuit board (not shown), tin solder can be filled in the through holes 17a to electrically connect the IC chip 12 to the circuit board (not shown).

When the opening 11f is sealed by the cover 14, the support member 15 keeps the cover 14 spaced from the solder wires 13 and the solder areas 11g of the carrier 11 to further prevent the solder wires 13 and the solder areas 11g from damage caused by the cover 14 directly squeezing the solder wires 13 and the solder areas 11g. The gaps formed between the cover 14 and the carrier 11 around the support members 15 are sealed by the bonding agent 16 to keep the receiving chamber 11c in an airtight condition.

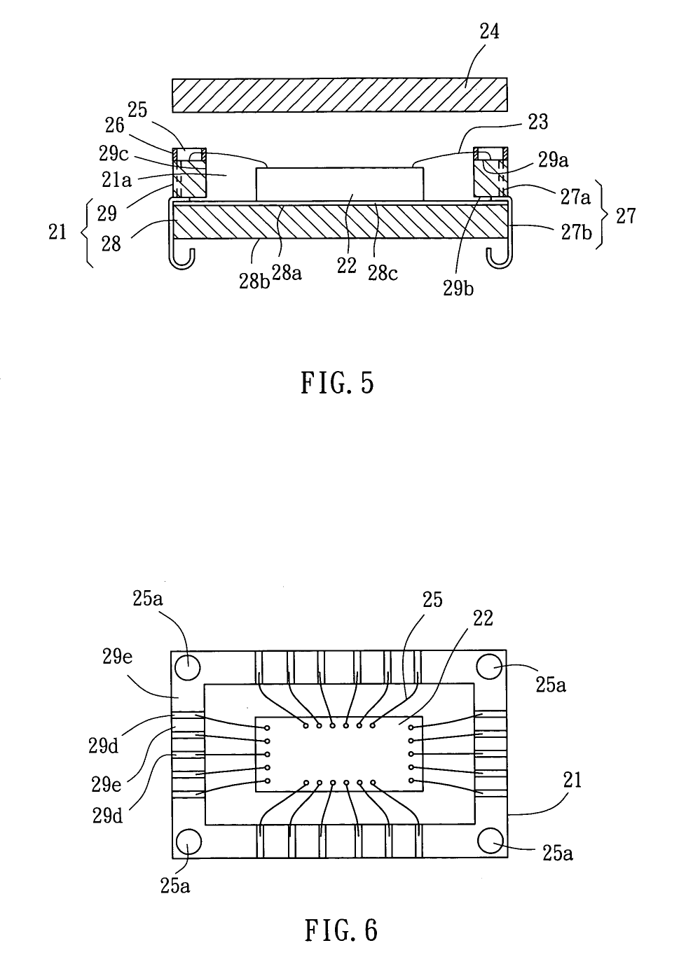

FIGS. 5 and 6 show the IC chip package 20 according to a second preferred embodiment of the present invention. According to this preferred embodiment, the IC chip package 20 is comprised of a carrier 21, a chip 22, a plurality of solder wires 23, a cover 24, a support member 25, a bonding agent 26, and connecting means 27, being similar to the aforementioned embodiment but having difference as follows.

The carrier 21 includes a plate member 28 and a frame member 29. The plate member 28 has a top side 28a, a bottom side 28b, and a metal waterproof layer 28c covered on the top side 28a. The frame member 29 has a top side 29a, a bottom side 29b, and an opening 29c running through the top side 29a and the bottom side 29b. The top side 29a has a plurality of solder areas 29d and non-solder areas 29e alternately arranged. The bottom side 29b of the frame member 29 is fixed to the metal waterproof layer 28c of the plate member 28. A receiving chamber 21a is defined by the opening 29c of the frame member 29 and the top side 28a of the plate member 28 for accommodating the IC chip 22.

Further, the support member 25 is formed of a plurality of short columns 25a respectively protruded from the non-solder areas 29e at the top side 29a of the frame member 29. When the receiving chamber 21a is sealed by the cover 24, the short columns 25a are mounted on the non-solder areas 29e at top sides thereof, keeping the cover 24 spaced from solder wires 23 and the solder areas 29d of the frame member 29.

The connecting means 27 includes a plurality of through holes 27a in communication between the solder areas 29d and the bottom side 29b of the frame member 29, and a plurality of metal pins 27b. Each of the metal pins 27b has an end fixedly connected between the bottom side 29b of the frame member 29 and the top side 28a of the plate member 28 and electrically connected to the through hole 27a, and the other end located outside the carrier 21 and bent into a predetermined shape.

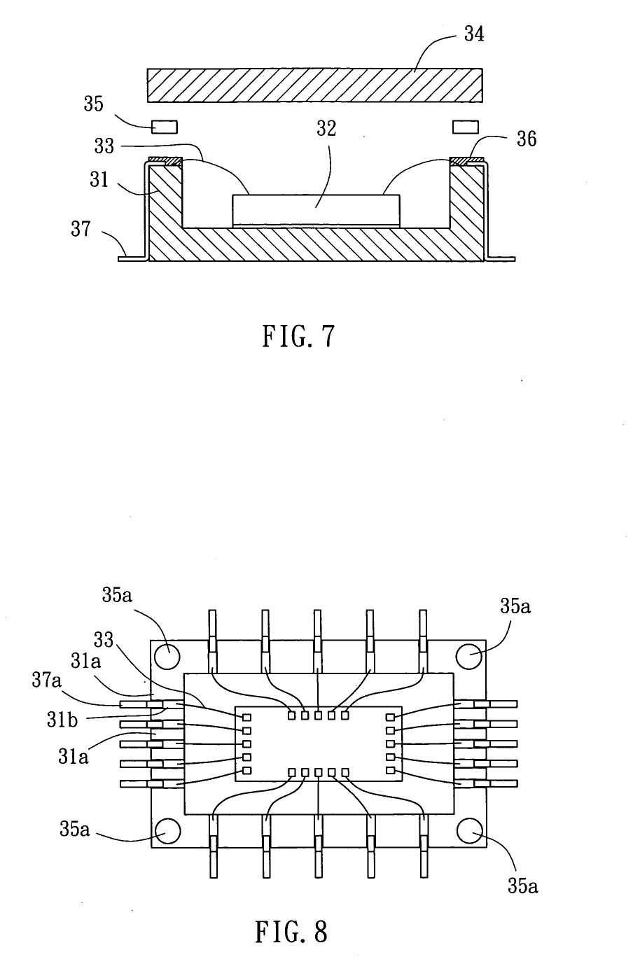

FIGS. 7 and 8 show the IC chip package 30 according to a third preferred embodiment of the present invention. According to this preferred embodiment, the IC chip package 30 is comprised of a carrier 31, a chip 32, a plurality of solder wires 33, a cover 34, a support member 35, a bonding agent 36, and connecting means 37, being similar to the aforementioned embodiments but having difference as follows.

The support member 35 includes a plurality of short columns 35a bonded to the non-solder areas 31a of the carrier 31 around the opening of the carrier 31 by the bonding agent 36. When the opening of the carrier 31 is sealed by the cover 34, the short columns 35a are held between the non-solder areas 31a of the carrier 31 and the cover 34 to keep the cover 34 spaced from the solder wires 33 and the solder areas 31b.

Further, the connecting means 37 includes a plurality of metal pins 37a. The metal pins 37a each have an end electrically connected to the solder areas 31b of the carrier 31 and the other end located outside the carrier 31 and bent into a predetermined shape.

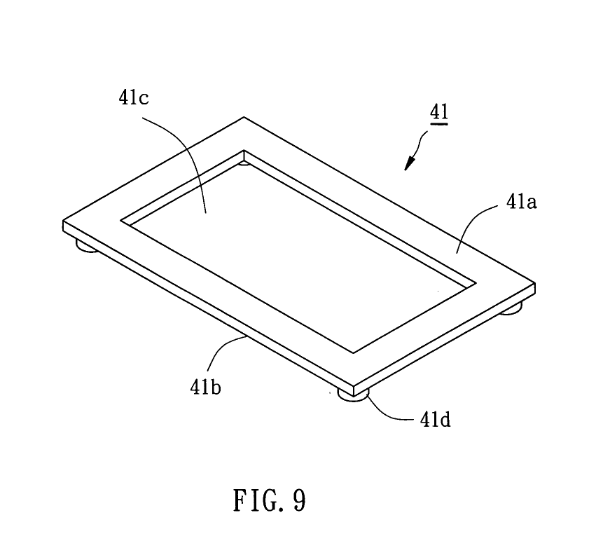

FIG. 9 shows the IC chip package constructed according to a fourth preferred embodiment of the present invention. This preferred embodiment is similar to the aforesaid third preferred embodiment, but having difference as follows.

The support member is a frame 41, which has a top side 41a, a bottom side 41b, a slot 41c running through the top side 41a and the bottom side 41b, and a plurality of short legs 41d formed at the bottom side 41b around the slot 41c. The short legs 41d are bonded to the non-solder areas (not shown) of the carrier (not shown) to keep the bottom side 41b spaced from the solder wires (not shown) and the solder areas (not shown) of the carrier (not shown). Further, the gaps formed between the carrier (not shown) and the frame 41 are sealed by the bonding agent (not shown).

1. An IC chip package comprising:
a carrier having a top side, a bottom side, a receiving chamber, an opening formed at said receiving chamber, and a plurality of solder areas and non-solder areas, said solder areas and non-solder areas being alternately arranged around said opening;
an IC chip fixedly mounted inside said receiving chamber and having a plurality of solder pads;
a plurality of solder wires respectively electrically connected between said solder pads and said solder areas;
a cover mounted on said carrier for sealing said opening of said receiving chamber;
a support member held between said non-solder areas of said carrier and said cover; and
a bonding agent disposed between said carrier and said cover for fixing said cover to said carrier.

2. The IC chip package as defined in claim 1, wherein said cover comprises a top side and a bottom side; said support member is protruded from the bottom side of said cover.

3. The IC chip package as defined in claim 1, wherein said support member is protruded from said non-solder areas of said carrier.

4. The IC chip package as defined in claim 1, wherein said support member is a frame member having a slot and a plurality of short legs, said slot corresponding to said opening of said receiving chamber, each of said short legs being formed at a bottom side of said frame member and bonded to said non-solder area of said carrier.

5. The IC chip package as defined in claim 1, wherein said receiving chamber has a bottom wall and an upright peripheral wall, said peripheral wall being located around an edge of said bottom wall and surrounding said opening of said receiving chamber.

6. The IC chip package as defined in claim 1, wherein said carrier comprises a plate member and a frame member, said plate member having a bottom side, a top side, and a metal waterproof layer disposed on the top side of said plate member, said frame member having a top side, a bottom side, and a slot running through the top and bottom sides of said frame member; said receiving chamber of said carrier is defined by said slot of said frame member and the top side of said plate member.

7. The IC chip package as defined in claim 6 further comprising connecting means, said connecting means having a plurality of through holes and metal pins, said through holes communicating with said non-solder areas of said carrier and the bottom side of said frame member, each of said metal pins having an end held between the bottom side of said frame member and the top side of said plate member and electrically connected to said through hole, and a second end located outside said carrier and bent into a predetermined shape.

8. The IC chip package as defined in claim 1 further comprising connecting means for electrically connecting said solder areas of said carrier to the outside of said carrier.

9. The IC chip package as defined in claim 8, wherein said connecting means comprises a plurality of through holes formed around said carrier and communicating with said solder areas and the bottom side of said carrier.

10. The IC chip package as defined in claim 8, wherein said connecting means comprises a plurality of metal pins, said metal pins each having an end electrically connected to said solder areas of said carrier and a second end located outside of said carrier and bent into a predetermined shape.

11. The IC chip package as defined in claim 1, wherein said solder areas of said carrier are solder pads.
